(19) United States
(12) Patent Application Publication
(10) Pub. No.: US 2025/0330088 A1
(43) Pub. Date: Oct. 23, 2025

(54) DIRECT CURRENT (DC) TO DC BOOST CONVERTER AND LOAD MONITORING CIRCUIT

(71) Applicant: Texas Instruments Incorporated, Dallas, TX (US)

(72) Inventors: Venkatesh Kadlimatti, Bangalore (IN); Ankitha M, Bangalore (IN); Aniruddha Periyapatna Nagendra, Bangalore (IN)

(21) Appl. No.: 18/643,159

(22) Filed: Apr. 23, 2024

(51) Int. Cl. H02M 3/158; H02M 1/088

(52) U.S. Cl. CPC H02M 3/158; H02M 1/088

(57) ABSTRACT

A technique for load monitoring. The technique includes measuring a first time period indicating an amount of time for recharging and discharging the charging circuit for a predetermined number of recharge cycles. The technique also includes measuring a second time period indicating a total amount of time in the predetermined number of recharge cycles. The technique further includes determining a duty cycle based on the first time period and the second time period and adjusting an inductor peak current circuit based on the determined duty cycle.

### BACKGROUND

Modern integrated circuits (ICs), both analog and digital, often have varying power needs. For example, certain circuits of the IC may operate at a voltage that is different from that provided by a power source, such as a battery. Further, power demands may vary in real time, for example, based on what an IC doing. For example, one or more power converter circuits may be used to step down (or up) a direct current (DC) voltage from a battery voltage to another DC voltage compatible with a processor, transmitter, sensor, etc. that is operating with a certain load. In such cases, DC to DC (DCDC) power converter circuits may be incorporated as a part of the IC to help manage voltage and/or current being supplied to various parts of the IC.

### SUMMARY

Aspects of this disclosure relate to an apparatus. The apparatus includes a switch controller couplable to a power converter circuit, wherein the switch controller is configured to cause charging or discharging of the power converter circuit; a first counter circuit configured to receive an indication that the switch controller circuit has caused charging or discharging, wherein the first counter circuit is configured to measure a first time period indicating an amount of time the switch controller circuit has caused charging or discharging for a predetermined number of charge/discharge cycles; a second counter circuit configured to receive an indication that the switch controller circuit has caused charging or discharging, wherein the second counter circuit is configured to measure a second time period indicating a total amount of time in the predetermined number of charge/discharge cycles; and a load computation circuit coupled to the first counter circuit and the second counter circuit, wherein the load computation circuit is configured to: determine a duty cycle based on the first time period and the second time period; and adjust how often the switch controller circuit causes charging or discharging based on the determined duty cycle.

Another aspect of the present disclosure relates to a technique for load monitoring. The technique includes receiving an indication that a switch controller circuit has caused charging or discharging, measuring a first time period indicating an amount of time the switch controller circuit has caused charging or discharging for a predetermined number of charge/discharge cycles, receiving an indication that the switch controller circuit has caused charging or discharging, determining a duty cycle based on the first time period and the second time period, and adjusting how often the switch controller circuit cause charging or discharging based on the determined duty cycle.

Another aspect of the present disclosure relates to a system for power conversion. The system includes a power converter circuit including one or more drivers configured to couple a power source to an energy storage device that is coupled to a load; a first counter circuit coupled to the power converter circuit, wherein the first counter circuit is configured to measure a first time period indicating an amount of time for recharging and discharging the power converter circuit for a predetermined number of charge/discharge cycles; a second counter circuit coupled to the power converter circuit, wherein the second counter circuit is configured to measure a second time period indicating a total amount of time in the predetermined number of charge/discharge cycles; and a duty cycle circuit coupled to the first counter circuit and the second counter circuit, wherein the duty cycle circuit is configured to: determine a duty cycle of the power converter circuit based on the first time period and the second time period; and adjust an amount of time the power converter circuit is charged or discharged based on the determined duty cycle.

### BRIEF DESCRIPTION OF THE DRAWINGS

For a detailed description of various examples, reference will now be made to the accompanying drawings in which:

FIG. 1 illustrates current profile waveforms for an inductor of a DC-DC power converter circuit, in accordance with aspects of the present disclosure.

FIG. 2 is a circuit diagram of an adjustable power converter circuit, in accordance with aspects of the present disclosure.

FIG. 3 is a signal diagram illustrating signals of a load meter for a power converter circuit operating in a DCM mode, in accordance with aspects of the present disclosure.

FIG. 4 is a signal diagram illustrating signals of a load meter operating in a continuous conduction mode (CCM) or discontinuous conduction (DCM)+CCM mode, in accordance with aspects of the present disclosure.

FIG. 5 is a circuit diagram of an adjustable power converter circuit including voltage undershoot detection and mitigation, in accordance with aspects of the present disclosure.

FIG. 6 is a circuit diagram illustrating an Ipeak circuit, in accordance with aspects of the present disclosure.

FIG. 7 is a flow diagram illustrating an overview of a technique for controlling a power converter, in accordance with aspects of the present disclosure.

### DETAILED DESCRIPTION

Often, power converter circuits may be adjusted to provide a fixed voltage to a varying load. For example, an amount of current being provided by a power converter circuit may be adjusted to correspond with current used by the load. Such adjustments based on current usage can increase the efficiency of the power converter. For example, a power converter circuit, such as a buck converter, may be adjusted by an inductor peak current (Ipeak) circuit. The Ipeak circuit may adjust a peak current that can be driven by an inductor of the buck convertor by controlling an amount of time the inductor is charged and discharged. In some examples, adjusting the amount of time the inductor is charged can increase efficiency of the buck converter by reducing an amount of current overshoot and undershoot to better match the load. In some cases, a load meter may be used to sense a duty cycle of the inductor to determine whether the charging/discharging of the inductor matches the load. Therefore, techniques to improve load meter accuracy and/or load meter speed may be useful. Of note, while discussed in the context of a buck converter, the concepts discussed herein are not intended to be limiting and the concepts discussed herein may be applied to other types of power converter circuits, such as boost convertors, buck-boost convertors, Cuk convertors, and the like.

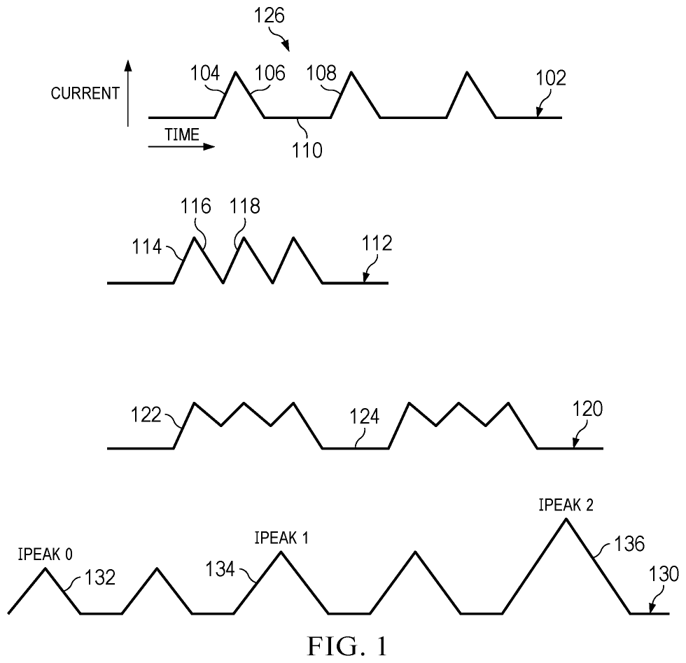

FIG. 1 illustrates current profile waveforms for an inductor of a DC-DC power converter circuit, in accordance with aspects of the present disclosure. A power converter circuit may include energy storage devices such as an inductor and a capacitor. In an example, a control circuit determines an amount of time that the inductor is charged and discharged to control the charge and discharge of the capacitor and thereby regulate the output voltage. During a charge phase, the control circuit may couple the inductor to a power supply until the current through the inductor rises to a configurable threshold (Ipeak). The current through the inductor may be measured externally or internally. Once the current meets or exceeds the Ipeak value, the control circuit may couple the inductor to a lower voltage (e.g., ground) so that the current through the inductor falls in a discharge phase. In some cases, a power converter circuit may operate in different operating modes for charging/discharging the inductor characterized by when the next charge phase occurs. For example, current profile waveform 102 illustrates a current 126 through the inductor of the power converter circuit on a vertical axis over time on a horizontal axis operating in a discontinuous conduction (DCM) mode with a constant Ipeak value. In DCM operation, the inductor, as shown current profile waveform 102, may be charged 104 at a certain current until Ipeak is met, discharged 106 to zero, and then charged 108 again with deadtime 110 occurring between discharging 106 the inductor and charging 108 the inductor. In some cases, the DCM operation may be a normal mode of operation for the power converter circuit.

Sometimes, the power converter circuit may also operate in a continuous conduction mode (CCM) or burst mode where a charge phase begins immediately after a discharge phase with little to no measurable deadtime. The charge phase may begin even before the inductor current falls to zero. In CCM operation of waveform 112, the inductor may be charged 114 (e.g., charge cycle, charge phase) at a certain current, discharged 116 (e.g., discharge cycle, discharge phase), and charged 118 again (e.g., a second charge cycle, second charge phase). The inductor may be charged 118 immediately after being discharged 116, very shortly after being discharged 116, or may occur before the inductor is fully discharged 116 to zero. Other times, the power converter circuit may operate in DCM+CCM mode, as illustrated in current profile waveform 120, where the inductor may be charged/discharged multiple times 122 as in CCM operation, followed by an amount of deadtime 124 as in DCM operation.

In some cases, it may be useful to adjust the Ipeak value. Current profile waveform 130 illustrates a current (on a vertical axis) of an inductor over time (on a horizontal axis) as the Ipeak value is adjusted. Adjusting the Ipeak value can change the amount of time the inductor is allowed to charge from the supply voltage and discharge, allowing the inductor to be charged to a higher current. For example, in current profile waveform 130, where the Ipeak is set to a first setting 132, the inductor may be charged for a certain amount of time to a first current. Increasing the Ipeak value to a second setting 134 may cause the inductor to be charged a longer amount of time to a higher current. Increasing the Ipeak value to a third setting 136 may cause the inductor to be charged even longer to another higher current. Charging the inductor to a higher current or lower current allows the inductor to better maintain a regulated voltage as the load changes. For example, as the load increases, the inductor may be charged to a higher current to maintain the regulated voltage. If the load decreases, the inductor may be charged to a lower voltage to maintain the regulated voltage. Additionally, the inductor may be charged to a higher voltage to avoid or exit CCM/DCM operation. For example, charging the inductor to a higher current may allow the inductor to provide the regulated voltage for a longer period of time before another charge cycle is needed, potentially allowing for deadtime/increased deadtime before the next charge cycles.

The Ipeak and other parameters of a power converter circuit may be adjusted based on changes in a load as measured by a load meter. An example load meter circuit measures load power demand based on current operating conditions of the power converter circuit such as charging (T_{ON}) duration, discharging (T_{OFF}) duration, and/or deadtime duration. Generally, a load meter should be able to sense a load for the inductor in all of the operating modes. However, a load meter which measures a load of an inductor using a fixed time interval may not be able to accurately determine the load's power demand in all of the operating modes. For example, a load meter which senses at a fixed time interval may not be able to synchronize when measurements are taken with the charge/discharge cycle intervals, which may lead to potential errors as measurements may be performed at different parts of the charge/discharge cycle from one measurement to another.

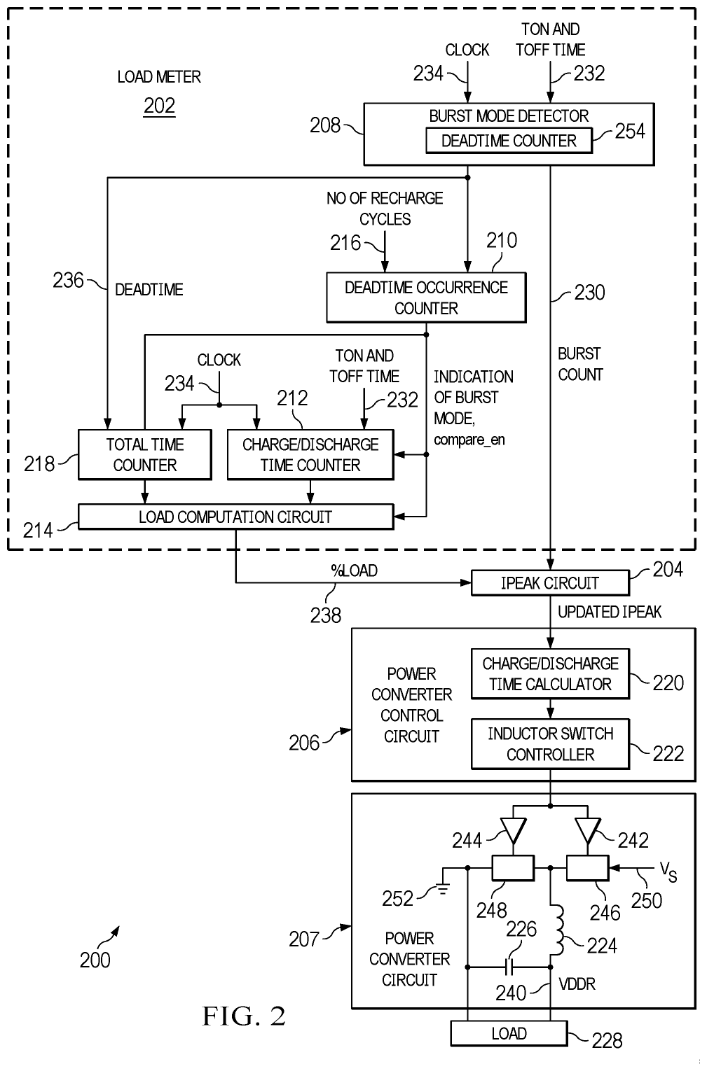

FIG. 2 is a circuit diagram of an adjustable power converter circuit 200, in accordance with aspects of the present disclosure. An adjustable power converter circuit 200 may be a circuit which can alter (e.g., convert) an input voltage and current into a range of output voltages and currents and maintain a selected output voltage for a varying load. In FIG. 2, the adjustable power converter circuit 200 includes a load meter 202 electronically coupled to an Ipeak circuit 204. The Ipeak circuit 204 is electronically coupled to a power converter control circuit 206, which is electronically coupled to a power converter circuit 207. The power converter circuit 207 in this example, is a buck converter. The power converter circuit 207 includes an inductor 224, which in turn is coupled to a capacitor 226 and a load 228

The load meter 202 of FIG. 2 includes a burst mode detector 208 electronically coupled to a deadtime occurrence counter 210, and a total time counter 218. The deadtime occurrence counter 210 is electronically coupled to a charge/discharge time counter 212, a load computation circuit 214, and the total time counter 218. The charge/discharge time counter 212 and the total time counter 218 are both electronically coupled to the load computation circuit 214. The load computation circuit 214 may output 238 an indication of a load percentage (e.g., as a duty cycle) of the power converter control circuit 206. The burst mode detector 208 is also electronically coupled to the Ipeak circuit 204. The Ipeak circuit 204 is electronically coupled to a charge/discharge time calculator 220 of the power converter control circuit 206.

The power converter control circuit 206 in this example includes the charge/discharge time calculator 220 which is electronically coupled to an inductor switch controller 222. The inductor switch controller 222 is electronically coupled a first driver 242 and a second driver 244 of the power converter circuit 207. The first driver 242 is electrically coupled to a first switch 246 of the power converter circuit 207 and the second driver 244 is electrically coupled to a second switch 248 of the power converter circuit 207. The first switch 246 may be a metal oxide semiconductor field effect transistor (MOSFET) such as a P-channel MOSFET (PMOS). The second switch may be a MOSFET such as a N-channel MOSFET (NMOS). In this example, the first switch 246 may control a connection between a supply voltage 250 (Vₛ) to the inductor 224 and the second switch may control a connection between a ground 252 (e.g., drain, return) and the inductor 224. The inductor 224 is coupled to the capacitor 226 and the load 228. The inductor switch controller 222 may control the first driver 242 and second driver 244 to open and close the first switch 246 and second switch 248. For example, the inductor switch controller 222 can output a T_{ON}/T_{OFF} state indication to the first driver 242 and second driver 244 to cause the first switch 246 and second switch to open and close to cause the inductor 224 to be charged and discharged to provide energy as an outputted regulated voltage 240 (VDDR) to the load 228. The capacitor 226 may help smooth the charging/discharging. The regulated voltage 240 may be an output voltage of the inductor 224 against the load 228. In some cases, the inductor switch controller 222 may be couplable (e.g., via electrical connectors, plugs, etc.) to the first driver 242 and second driver 244. In some cases, the first driver 242 and second driver 244 may be couplable to the first switch 246 and second switch 248 of the power converter circuit 207.

In some cases, the inductor switch controller 222 may couple/decouple the supply voltage 250 to maintain the regulated voltage 240. The inductor switch controller 222 may activate/deactivate the first driver 242 and second driver 244 to cause the first switch 246 and the second switch 248 to couple/decouple the supply voltage 250 and the ground 252 to the inductor 224. The first driver 242 and second driver 244 may each include a series of inverters for controlling a gate of the first switch 246 and second switch 248 respectively. The gate of the first switch 246 may couple/decouple the supply voltage 250 (Vₛ) with the inductor 224 to charge the inductor 224. Similarly, the gate of the second switch 248 may couple/decouple the ground 252 with the inductor 224 to discharge the inductor 224. When the first switch 246 couples the supply voltage 250 with the inductor 224, the second switch 248 decouples the ground 252 and the power converter circuit 207 is in a T_{ON} state. Similarly, when the second switch 248 couples the ground 252 with the inductor 224, the first switch 246 decouples the supply voltage 250 and the power converter circuit 207 is in a T_{OFF} state.

Whether the power converter circuit 207 is in a T_{ON} state, T_{OFF} state or neither may be output by the inductor switch controller to the first switch 246, second switch 248, along with the burst mode detector 208 and charge/discharge time counter. As detailed below, the charge/discharge time calculator 220 may determine times for when the T_{ON} state, T_{OFF} state, and/or neither should be set and the charge/discharge time calculator 220 may indicate theses times to the inductor switch controller 222. The inductor switch controller 222 may generate an indication of the T_{ON} state, T_{OFF} state, and/or neither to activate/deactivate the first driver 242 and second driver 244 to open/close the gates of the first switch 246 and/or second switch 248.

In the T_{ON} state, the first driver 242 causes the first switch 246 to act as a closed switch (e.g., cause a transistor of the first switch 246 to operate in an active/saturation mode), and the second driver 244 causes the second switch 248 to act as an open switch (e.g., cause a transistor of the second switch 248 to operate in a cutoff mode). As a result, the supply voltage 250 is coupled to the inductor 224 through the first switch 246 and the inductor 224 and capacitor 226 may be charged to store energy. In the T_{OFF} state, the first driver 242 causes the first switch 246 to act as an open switch (e.g., cause the transistor of the first switch 246 to operate in a cutoff mode), and the second driver 244 causes the second switch 248 to act as a closed switch (e.g., cause the transistor of the second switch 248 to operate in an active/saturation mode). As a result, the ground 252 is coupled to the inductor 224 through the second switch 248 and the inductor 224 may discharged (e.g., through the load 228). The inductor 224 current increases as the inductor 224 is charged in the T_{ON} state (e.g., as shown at charged 104, 108, 114, and 118 of FIG. 1). The inductor 224 current decreases when the inductor 224 is discharged via the load 228 (e.g., as shown at discharged 106 and 116 of FIG. 1), such as when the power converter circuit 207 is in the T_{OFF} state. In some cases, if both first switch 246 and the second switch 248 are in the closed state (e.g., neither the supply voltage 250 nor the ground are coupled to the inductor 224), the power converter circuit 207 is in a deadtime and is not in either the T_{ON} state or the T_{OFF} state. In the deadtime, the inductor 224 may maintain its current, which may be zero.

The regulated voltage 240 provided to the load 228 by the power converter circuit 207 may be a function of how often (e.g., over a given time period) the inductor is charged (e.g., in a T_{ON} state) and discharged (e.g., in a T_{OFF} state). In some cases, the amount of time the inductor is allowed to charge and discharge may be determined based on an Ipeak value provided by the Ipeak circuit 204 and a lookup table of the charge/discharge time calculator 220. For example, different Ipeak values may map to different charge and discharge times in the lookup table and higher Ipeak values may generally correlate with a longer T_{ON} and T_{OFF} times. Based on the Ipeak value and lookup table, the charge/discharge time calculator 220 may indicate to the inductor switch controller 222 when to enter the T_{ON} state, T_{OFF} state, and deadtime. The inductor switch controller 222, as indicated above, may then control the first switch 246 and second switch 248 based on the indication from the charge/discharge time calculator 220.

The Ipeak circuit 204 may be adjustable (e.g., has settings) and a setting on the Ipeak circuit 204 may affect the Ipeak value and thereby adjust a peak current that may be used to charge the inductor 224 (and by extension, adjust the peak current driven by the inductor 224). Adjusting the peak current driven by the inductor 224 may adjust, via the charge/discharge time calculator 220, an amount of time the inductor 224 may charge from the supply voltage 250. In some cases, the Ipeak circuit 204 may be integrated with the charge/discharge time calculator 220.

In some cases, the load meter 202 may be an FSM that may provide information about the current being drawn by load 228. The load 228 may be a component of the SoC which uses the converted power, such as a radio transmitter, processing circuit, etc., and the amount of current drawn by the load 228 may vary, for example, based on what operations the SoC is performing. The information about the current being drawn by the load 228 may be used to adjust the setting of the Ipeak circuit 204 to help improve efficiency, for example, by adjusting the charge/discharge cycles of the inductor 224 for the current being drawn.

In some cases, the load meter 202 may be configured to measure the current being drawn by the load 228 coupled to a power converter control circuit 206 as a function of a number of charge/discharge cycles rather than a fixed time interval when the power converter circuit is operating in the DCM mode (e.g., non-burst). In other words, instead of measuring the how many charge/discharge cycles occur in a fixed interval of time, which may vary considerably for smaller intervals of time, the number of charge/discharge cycles is fixed and the amount of time for those charge/discharge cycles is measured. Measuring the load based on charge/discharge cycles may allow the load meter to better adapt to dynamic load conditions to provide more accurate and timely load information as compared to load measurements using a fixed time interval. For example, the load of the power converter circuit may be measured over a measurement cycle, which may be a configurable number of charge/discharge cycles over which the load may be measured, such as three charge/discharge cycles. Measuring the load based on the number of charge/discharge cycles helps align the measurements with respect to the charge/discharge cycles and deadtime and helps ensure that measurements are not performed at different parts of the charge/discharge cycle/deadtime from one measurement to another, such as with time interval based measurements, which can resulting in inaccurate measurements.

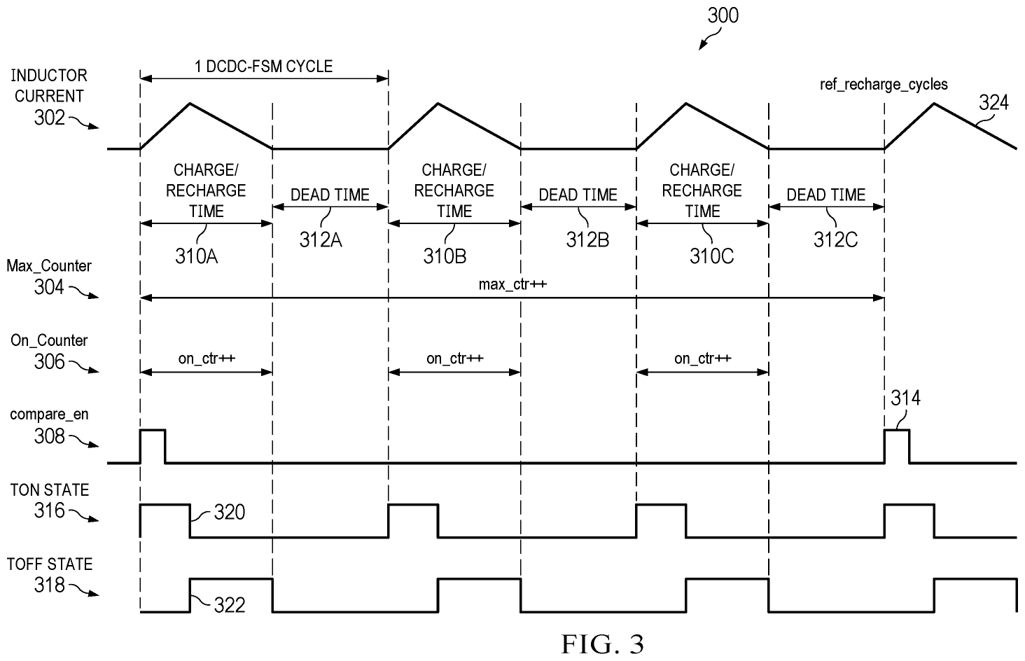

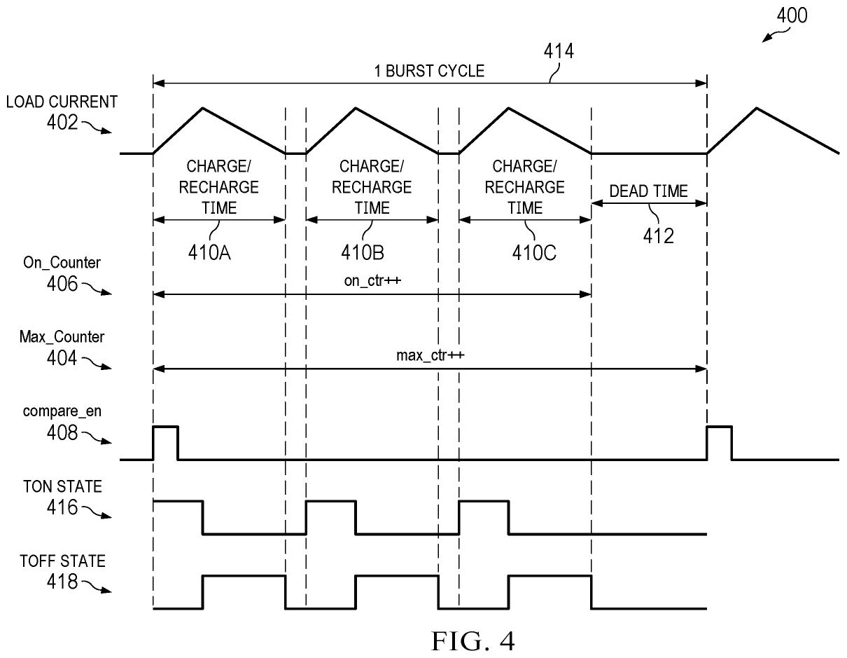

The deadtime occurrence counter 210 may count a number of deadtimes (or number of charge/discharge cycles) that have occurred. The deadtime occurrence counter 210 may receive information about whether the power converter control circuit 206 is in the burst mode, along with a deadtime indication 236 indicating whether the power converter control circuit 206 is in deadtime. The deadtime occurrence counter 210 may also receive an indication of a total number of charge/discharge cycles 216 that have been measured in the current measurement cycle. In some cases, the total number of charge/discharge cycles that indicate the end of the measurement cycle may be configurable and the deadtime occurrence counter 210 may include one or more registers which may receive the indication of the total number of charge/discharge cycles 216 that are in the measurement cycle. In some cases, the one or more registers may be memory mapped registers. This total number of charge/discharge cycles in the measurement cycle may be used by the deadtime occurrence counter to determine how long a measurement cycle is. For example, in the non-burst mode (e.g., as indicated by the burst mode detector 208) the deadtime occurrence counter 210 may count a number of charge/discharge cycles for a current measurement cycle. For example, in the non-burst mode, a deadtime may follow a charge/discharge cycle and the deadtime occurrence counter 210 may count a number of deadtime indications 236 received and compare the number of deadtime indications 236 to the total number of charge/discharge cycles that are in the measurement cycle. When the count of the number of deadtime indications 236 for the current measurement cycle reaches the total number of charge/discharge cycles in the measurement cycle (e.g., at a start of a charge/discharge cycle that occurs after a deadtime corresponding to the last charge/discharge cycle), the deadtime occurrence counter 210 may set (e.g., assert, change, update, send, etc.) a compare_en signal (e.g., compare_en 308 of FIG. 3, compare_en 408 of FIG. 4) indicating a beginning and/or an end of the current measurement cycle. In some cases, an end of the current measurement cycle may also indicate a start of a next measurement cycle. The compare_en signal may be output to the charge/discharge time counter 212, total time counter 218, and the load counter 242.

The charge/discharge time counter 212 may receive the indication 232 whether the inductor 224 is charging/discharging/neither, an indication of burst mode, compare_en, the number of charge/discharge cycles over which to measure the load, and the clock signal 234. The charge/discharge time counter 212 may determine a value for a counter on_counter. For example, the charge/discharge time counter 212 may count a number of clock cycles where the indication 232 indicates that the power converter control circuit 206 is charging or discharging (e.g., T_{ON} or T_{OFF} are on) over the measurement cycle (e.g., based on compare_en). The counted number of clock cycles may be set as a value of the on_counter. The charge/discharge time counter 212 may output the on_counter value to the load computation circuit 214.

The total time counter 218 may receive the clock signal 234, deadtime indication 236, an indication of burst mode, and compare_en. The total time counter 218 may determine a value for max_counter (e.g., max_counter 304 of FIG. 3 and max_counter 404 of FIG. 4) and output the determined max_counter value to the load computation circuit 214. For example, the total time counter 218 may count a total number of clock cycles that occur between a start of a measurement cycle and an end of the measurement cycle. In some cases, the compare_en signal may be asserted at an end of the measurement cycle and the deadtime occurrence counter 210 may assert the compare_en signal at the end of the measurement cycle.

The load computation circuit 214 may receive the on_counter value and max_counter value and determine the load of the power converter control circuit 206 based on the values. In some cases, the load computation circuit 214 may determine the load as a duty cycle of the power converter control circuit 206. The duty cycle may be a percentage of time the power converter control circuit 206 (e.g., the inductor 224) is charging/discharging versus a total amount of time. In some cases, the duty cycle may be determined based on bit shifting and addition/subtraction. The load computation circuit 214 may output 238 the determined duty cycle (e.g., as a percent load) of the power converter control circuit 206 and inductor 224 to the Ipeak circuit 204. As detailed below, the Ipeak circuit 204 may increase an Ipeak value (e.g., to increase an amount of time that the inductor 224 is charged/discharged) where the duty cycle is above a high load percentage level and the Ipeak circuit 204 may decrease the Ipeak value (e.g., to decrease an amount of time that the inductor 224 is charged/discharged) where the duty cycle is below a low load percentage level.

The burst mode detector 208 of the load meter 202 may receive an indication 232 whether the inductor 224 is charging (e.g., T_{ON} is on), discharging (e.g., T_{OFF} is on), or neither (e.g., deadtime where both T_{ON} and T_{OFF} are off) along with a clock signal 234. For example, as indicated above, the charge/discharge time calculator 220 may indicate to the inductor switch controller 222 when to enter the T_{ON} state, T_{OFF} state, or deadtime and the inductor switch controller 222 may control the first switch 246 and second switch 248 to charge and discharge the inductor 224 based on the indication from the charge/discharge time calculator 220. The indication 232 whether the inductor 224 is charging (e.g., T_{ON} set), discharging (T_{OFF} set) or neither (neither T_{ON} nor T_{OFF} are set) may be received from any of the charge/discharge time calculator 220, inductor switch controller, first switch 246, second switch 248, first driver 242, second driver 244, and/or any combination thereof. For example, the indication 232 whether the inductor 224 is charging, discharging, or neither may be based on whether the first switch 246 and second switch 248 are open or closed. When the first switch 246 couples the supply voltage 250 with the inductor 224, T_{ON} may be set. When the ground 252 is coupled to the inductor 224 through the second switch 248 T_{OFF} may be set. When the first switch 246 and the second switch 248 are open, then neither T_{ON} nor T_{OFF} are set.

The burst mode detector 208 may detect when the power converter control circuit 206 is operating in the burst mode. The burst mode detector 208 may include a deadtime counter 254 which counts a number of clock cycles that occur during deadtime (e.g., where the inductor 224 is neither charging nor discharging). For example, the deadtime counter 254 may count the number of clock cycles where both T_{ON} and T_{OFF} are not set. The burst mode detector 208 may output a deadtime indication 236 when a deadtime is detected. Based on the indication 232 whether the inductor 224 is charging, discharging, or neither, the burst mode detector 208 may detect that the inductor 224 has changed from discharging to neither and count a number of clock cycles (e.g., by the deadtime counter 254) in which the inductor 224 is neither charging nor discharging between discharging and the next charging. If the number of clock cycles where the inductor 224 is neither charging nor discharging is less than a threshold number of clock cycles, the burst mode detector 208 may determine that the inductor 224 is in burst mode. The burst mode detector 208 may also detect that the inductor 224 has changed directly from discharging to charging without deadtime (e.g., based on the deadtime counter remaining at zero) as a part of determining whether the inductor 224 is in burst mode.

The burst mode detector 208 may indicate to the deadtime occurrence counter 210 and Ipeak circuit 204 whether a burst mode has been detected. In some cases, the burst mode detector 208 may also pass the indication 232 whether the inductor 224 is charging/discharging/neither to the deadtime occurrence counter 210. When a burst mode has been detected, the burst mode detector 208 may provide a burst count 230 to the Ipeak circuit 204. The burst count 230 may be a number of charge/discharge cycles that have occurred between two deadtimes. As described in more detail below, the Ipeak circuit 204 may compare the burst count 230 to a burst count 230 threshold. If the burst count 230 exceeds the burst count 230 threshold, the Ipeak circuit 204 may increase an Ipeak value to increase an amount of time the inductor 224 is charged/discharged. In some cases, how much the Ipeak value is increased may be based on how much the burst count 230 exceeds the burst count 230 threshold. For example, if the burst count 230 exceeds the burst count 230 threshold by a larger amount, the Ipeak value may be increased more than if the burst count 230 exceeds the burst count 230 threshold by a smaller amount. In some cases, the burst mode detector 208 and burst count 230 may provide a way to detect that the inductor 224 is operating in burst mode within one burst cycle (e.g., from a start of a charge cycle to a following deadtime).

In some cases, the indication that the burst mode has been detected may be output to the deadtime occurrence counter 210. As detailed below, the deadtime occurrence counter 210 may adjust how a counter (e.g., max_counter) of the deadtime occurrence counter 210 may be set based on the indication that the burst mode has been detected. Adjusting how the max_counter is set may allow the load computation circuit 214 to infer a load based on a number of charge/discharge cycles in a burst cycle rather than over a set number of charge/discharge cycles.

The deadtime occurrence counter 210 may adjust how certain counters of the deadtime occurrence counter 210 operate based on whether a burst mode has been detected. For example, as indicated above the max_counter (e.g., max_counter 304 of FIG. 3) may count a total number of clock cycles that occurred during a measurement cycle in a non-burst mode. In the burst mode, the max_counter may be adjusted to count a total number of clock cycles during a burst cycle. In some cases, the burst cycle may be from when an inductor is charged (e.g., enters T_{ON} state) after a deadtime until an end of a next deadtime.

In some cases, based on the indication that the burst mode has been detected, the load computation circuit 214 may infer the load of the inductor 224 based on a number of charge/discharge cycles in a burst cycle.

FIG. 3 is a signal diagram 300 illustrating signals of a load meter for a power converter circuit operating in a DCM mode, in accordance with aspects of the present disclosure. Signal diagram 300 includes an inductor current 302, which may be a current measured at the inductor, such as inductor 224 of FIG. 2, along with signals of the load meter, such as a max_counter 304, on_counter 306, and compare_en 308 signals, and information about whether the power converter circuit 207 is in the T_{ON} state 316 and T_{OFF} state 318. In some cases, the max_counter 304, on_counter 306, and compare_en 308 signals may be provided by the deadtime occurrence counter 210 of FIG. 2. Whether the power converter circuit 207 is in a T_{ON} state 316, T_{OFF} state 318 or neither may be indicated from any of the charge/discharge time calculator 220, inductor switch controller, first switch 246, second switch 248, first driver 242, second driver 244, and/or any combination thereof. In FIG. 3, the inductor current 302 illustrates the current of the inductor over time while the power converter circuit and/or inductor are operating in the DCM mode (e.g., non-burst mode). As shown, the inductor current 302 may change over time over a number of charge/discharge cycles. The inductor current 302 may be divided into two types of time. The first type of time may be charge/discharge time 310A-310C (collectively “charge/discharge time 310”) where the inductor is charged/discharged by the power converter circuit (e.g., corresponding to time for charge/discharge cycle), which is shown as an increase or decrease in the inductor current 302 over time. When in the T_{ON} state 316 (e.g., T_{ON} state 316 is set 320), the inductor current 302 may increase, when in the T_{OFF} state 318 (e.g., T_{OFF} state 318 is set 322), the inductor current 302 may decrease, and when in neither the T_{ON} state 316 nor the T_{OFF} state 318, there may be a deadtime. The second type of time may be deadtime 312A-312C (collectively “deadtime 312”) where the inductor is neither charging nor discharging, which is shown as a constant inductor current 302 over time.

In some cases, a measurement cycle may begin at a beginning of a charging cycle, such as at the beginning of charge/discharge time 310A, and end at the beginning of a charging cycle that is some configurable number of charging cycles later. In the illustration of FIG. 3, the number of charging cycles in a measurement cycle is set at three, and the end of the measurement cycle is the beginning of the charging cycle after deadtime 312C. At the end of a current measurement cycle, compare_en 308 may be set 314 (e.g., assert, change, update, send, etc.), indicating the end of the current measurement cycle. In some cases, the compare_en 308 signal may be set by the deadtime occurrence counter 210 of FIG. 2. In some cases, a next measurement cycle may begin at a start of a next charge/discharge cycle 324 after compare_en 308 was set 314.

As indicated above, the max_counter 304 may track a total number of clock cycles that are in a measurement cycle. In some cases, a total time counter, such as the total time counter 218 of FIG. 2, may perform operations with respect to the max_counter 304. In some cases, the max_counter 304 may be reset and may start counting (e.g., accumulating) clock cycles at a beginning of the measurement cycle and stop counting count clock cycles at the end of the measurement cycle at an end of a deadtime, such as deadtime 312C. As an example, if the number of charge/discharge cycles in a measurement cycle is three, then the max_counter may start counting (e.g., accumulating) clock cycles at a start of a charge/discharge time, such as charge/discharge time 310A, which is at the start of the measurement cycle, and stop counting clock cycles at the end of the measurement cycle after three charge/discharge cycles (e.g., based on the compare_en 308 signal being set) to determine the max_counter 304.

As indicated above, the on_counter 306 may count a number of clock cycles that occur during the charge/discharge times 310 for the inductor current 302. In some cases, a charge/discharge time counter, such as the charge/discharge time counter 212 of FIG. 2, may perform operations with respect to the on_counter 306. The on_counter 306 may be reset and may start counting (e.g., accumulating) clock cycles at a beginning of the measurement cycle (which may start at the beginning of a charge/discharge time 310A) and count clock cycles that occur during the charge/discharge times 310 of the measurement cycle. The on_counter 306 may stop counting count clock cycles at the end of the measurement cycle (e.g., based on the compare_en 308 signal being set) or the on_counter 306 may be stopped at a start of a deadtime after the number of charge/discharge cycles has been reached. As an example, if the number of charge/discharge cycles over which to measure the load is three, then the on_counter 306 may start counting (e.g., accumulating) clock cycles at a start of a charge/discharge time, such as charge/discharge time 310A, which is at the start of the measurement cycle, and may count clock cycles occurring during the charge/discharge times 310. The on_counter 306 may be stopped when the compare_en 308 signal is set or at a start of a deadtime, such as deadtime 312C, after the number of charge/discharge cycles for the measurement cycle has been reached. In some cases, clock cycles in the deadtime after the number of charge/discharge cycles for the measurement cycle have been reached (e.g., deadtime 312C) are not counted by the on_counter 306. The number of clock cycles counted during charge/discharge times 310 may define a time period in which the power converter circuit was charging/discharging the inductor during the measurement cycle.

After values for max_counter 304 and on_counter 306 have been determined, the duty cycle may be determined. The duty cycle may be determined based on a comparison between a value of the max_counter 304 and a value of the on_counter 306. For example, as indicated above, the duty cycle may be a percentage of time the inductor is charging/discharging as measured by the value of the on_counter 306 divided by a total amount of time as measured by the max_counter 304. Based on the duty cycle, the Ipeak value may be adjusted to control, for example, how much time the inductor is charged. For example, a power converter circuit and/or inductor may operate efficiently within a range of duty cycles, such as within a 40% duty cycle to a 60% duty cycle, and based on the determined duty cycle, the Ipeak value may be adjusted higher to increase an amount of time spent charging within the charge/discharge cycle, or adjusted lower to decrease the amount of time spent charging within the charge/discharge cycle to bring the determined duty cycle within the range of duty cycles.

In some cases, it may be relatively expensive, in terms of time and/or area, to perform a division operation by values other than powers of two in digital logic. Rather than performing a divide operation to determine the duty cycle, the duty cycle determination may be approximated using bit shifting and addition/subtraction operations. For example, a ten percent duty cycle may be approximated by taking the max_counter 304 and dividing by eight, subtracting the max_counter 304 divided by 32, and adding the max_counter 304 divided by 128 (10% duty cycle˜ max_counter-8−max_counter/32+max_counter/128). This operation may be performed using bit shifts and addition/subtraction by taking the max_counter 304 and right shifting the binary value of the max_counter 304 by three, subtracting the max_counter 304 right shifted by five, and adding max_counter 304 right shifted by seven (10% duty cycle=max_counter>>−3-max_counter>>5+max_counter>>7). The resulting approximation of the 10% duty cycle for the max_counter 304 can then be compared to the on_counter 306. If the approximated 10% duty cycle does not exceed the on_counter 306, then an approximation of a 20% duty cycle may be determined by left shifting the approximation of the 10% duty cycle by 1 (20% duty cycle˜ 10% duty cycle<<1). If the approximated 20% duty cycle does not exceed the on_counter 306, an approximation of a 40% duty cycle may be determined by left shifting the approximated 10% duty cycle by 2 (40% duty cycle˜ 10% duty cycle<<2) and comparing the approximated 40% duty cycle to the on_counter 306 and so forth. When an approximated duty cycle, such as the approximated 40% duty cycle exceeds the on_counter 306, the duty cycle may be determined as the previous approximated duty cycle, such as the 20% duty cycle in this example.

While approximating the duty cycle may be less accurate than performing a divide operation, approximating the duty cycle may be performed relatively quickly while still providing sufficient accuracy for adjusting the Ipeak value setting. For example, a given power converter circuit and/or inductor, such as power converter control circuit 206 and inductor 224 of FIG. 2, may operate efficiently within a range of duty cycles, such as within a 40% duty cycle to a 60% duty cycle, and approximating the duty cycle (or determining the duty cycle using division) may provide sufficient accuracy to allow the Ipeak circuit to be adjusted to maintain a duty cycle within the range of duty cycles. For example, the load computation circuit 214 may approximate the duty cycle and output 238 the approximated duty cycle to the Ipeak circuit. The Ipeak circuit may compare the approximated duty cycle to a high load percentage level and/or low load percentage level to determine whether to adjust an Ipeak value. As detailed below, the Ipeak circuit may increase the Ipeak value (e.g., to increase an amount of time the inductor 224 is charged/discharged) where the duty cycle is above the high load percentage level and the Ipeak circuit 204 may decrease the Ipeak value (e.g., to decrease an amount of time the inductor 224 is charged/discharged) where the duty cycle is below the low load percentage level.

In some cases, a load meter may measure current load for a power converter circuit in the DCM mode as described above with respect to FIG. 3 without supporting measuring the current load for the power converter circuit in CCM and/or CCM+DCM modes (e.g., burst modes). For example, measuring the current load for the power converter circuit in the DCM mode without support for burst modes may be performed by a charge/discharge time counter, such as charge/discharge time counter 212 of FIG. 2, a total time counter, such as total time counter 218 of FIG. 2, and a load computation circuit, such as load computation circuit 214 of FIG. 2. Determination of compare_en 308 and the indication of deadtime may be performed, for example, by the charge/discharge time counter, in a manner substantially similar to that described above in conjunction with the burst mode detector and deadtime occurrence counter.

In some cases, the load meter may support measuring the load current for an inductor and/or power converter circuit operating in burst mode. The load meter may also adjust how a load current is measured when the inductor is operating in the burst mode. As discussed above, a burst mode detector, such as burst mode detector 208 of FIG. 2, may indicate when the inductor is in deadtime or in burst mode. For example, in some cases, the burst mode detector may receive an indication whether the inductor coupled to the power converter circuit is charging (e.g., T_{ON} is on), discharging (e.g., T_{OFF} is on), or neither (e.g., both T_{ON} and T_{OFF} are off) along with a clock signal. The burst mode detector may detect that the inductor has changed from discharging to either charging or neither charging nor discharging (e.g., based on an edge from T_{OFF} and another edge from T_{ON}). The burst mode detector may then count a number of clock cycles (e.g., by a deadtime counter) in which the inductor is neither charging nor discharging. If the number of clock cycles where the inductor is neither charging nor discharging is greater than or equals to a threshold number of clock cycles of deadtime (e.g., a deadtime threshold), then the burst mode detector may determine that the inductor is in a deadtime and not in burst mode. As an example, the deadtime threshold may be set to two and if, after discharging, the inductor is neither charging nor discharging for three clock cycles, the burst mode detector may determine that the inductor is in a deadtime and not in burst mode. The burst mode detector may then set the indication of deadtime.

If the number of clock cycles where the inductor is neither charging nor discharging is less than the deadtime threshold, then the burst mode detector may determine that the inductor is not in deadtime, but in a burst mode. The burst mode detector may not set the indication of deadtime and may set an indication of a burst mode, for example to the Ipeak circuit and deadtime occurrence counter. For example, where again the deadtime threshold is two, if, after discharging, the inductor immediately starts charging again or starts charging again after one clock cycle of neither charging nor discharging, the burst mode detector may determine that the inductor is not in deadtime, but rather that the inductor is in burst mode. In some cases, the load of the inductor may be measured over a single burst when the inductor is in burst mode. In some cases, a number of bursts over which the load of the inductor may be measured when the inductor is in burst mode may be configurable, for example, via a register.

FIG. 4 is a signal diagram 400 illustrating signals of a load meter operating in a CCM or DCM+CCM mode, in accordance with aspects of the present disclosure. Of note, while this example illustrates signals in a CCM mode, the concepts discussed with respect to the CCM mode may also apply to a DCM+CCM mode. Signal diagram 400 includes a load current 402 of an inductor, such as inductor 224 of FIG. 2, along with signals of the load meter, such as a max_counter 404, on_counter 406, and compare_en 408 signals and information about whether the power converter circuit 207 is in the T_{ON} state 416 and T_{OFF} state 418. In the illustrated examples, the measurement cycle is set to three charging cycles or one burst cycle 414, and in some cases, the max_counter 404, on_counter 406, and compare_en 408 signals measured over the measurement cycle may be provided by the deadtime occurrence counter 210 of FIG. 2. Whether the power converter circuit 207 is in a T_{ON} state 416, T_{OFF} state 418 or neither may be indicated from any of the charge/discharge time calculator 220, inductor switch controller, first switch 246, second switch 248, first driver 242, second driver 244, and/or any combination thereof. In FIG. 4, the load current 402 illustrates the current of the inductor over time while the power converter circuit and/or inductor are operating in the CCM mode (e.g., burst mode). As shown, the load current 402 includes three charge/discharge times 410A, 410B, and 410C (collectively “charge/discharge times 410”) separated by small amounts of time where the inductor is neither charging nor discharging that are below the deadtime threshold. When in the T_{ON} state 316 (e.g., T_{ON} state 316 is set 320), the inductor current 302 may increase, when in the T_{OFF} state 318 (e.g., T_{OFF} state 318 is set 322), the inductor current 302 may decrease, and when in neither the T_{ON} state 316 nor the T_{OFF} state 318 for longer than a deadtime threshold, there may be a deadtime. After charge/discharge time 410C, the load current 402 enters a deadtime 412 (e.g., longer than the deadtime threshold).

The on_counter 406 counts a number of clock cycles that occur during the charge/discharge times 410 for the load current 402. In some cases, a charge/discharge time counter, such as the charge/discharge time counter 212 of FIG. 2, may perform operations with respect to the on_counter 406. The on_counter 406, like on_counter 306 of FIG. 3, may start counting (e.g., accumulating) clock cycles at a beginning of the burst cycle 414 (which may start at the beginning of a charge/discharge time 410A) and count clock cycles that occur during the charge/discharge times 410 of the burst cycle 414 (the end of which is indicated by compare_en 408). In some cases, in burst mode operations, the on_counter 406 may continue to accumulate during the small amounts of time where the inductor is neither charging nor discharging that are below the deadtime threshold. For example, the charge/discharge time counter may receive an indication whether the inductor is charging/discharging/neither and a clock signal. If the number of clock cycles where the inductor is neither charging nor discharging is less than the deadtime threshold, the charge/discharge time counter may continue to accumulate the on_counter 406. Alternatively, the charge/discharge time counter may receive the indication of deadtime and accumulate the on_counter until an indication of deadtime is received (e.g., set). The on_counter 406 may stop counting count clock cycles at the end of the burst cycle 414 (e.g., based on the compare_en 408 signal being set) or the on_counter 406 may be stopped at a start of a deadtime (e.g., after an amount of time where the inductor is neither charging nor discharging exceeds the deadtime threshold). After the on_counter 406 is stopped, the value of the on_counter may be used for measuring the load.

The max_counter 404 may again track a total number of clock cycles that are in a burst cycle 414. In some cases, a total time counter, such as the total time counter 218 of FIG. 2, may perform operations with respect to the max_counter 404. In some cases, the max_counter 404 may start counting (e.g., accumulating) clock cycles at a beginning of the burst cycle 414 and stop counting count clock cycles at the end of the burst cycle 414 at an end of a deadtime, such as deadtime 412. In some cases, the max_counter 404 may stop counting based on the compare_en 408 signal and the value of the max_counter 404 may be used for measuring the load.

The compare_en 408 signal may be sent (e.g., asserted), for example, by the deadtime occurrence counter (e.g., deadtime occurrence counter 210 of FIG. 2). In some cases, based on an indication that that the inductor is operating in burst mode, and the indication of deadtime from the burst mode detector, the deadtime occurrence counter may assert the compare_en 408 signal at the end of a deadtime for a current burst cycle 414. For example, the deadtime occurrence counter may, for a current burst cycle 414 and based on the indication that the power converter circuit and/or inductor are operating in burst mode, detect an indication of deadtime being asserted. When the indication of deadtime is unasserted, the deadtime occurrence counter may determine that the current burst cycle 414 has ended and may assert the compare_en 408 signal.

After values for max_counter 404 and on_counter 406 have been determined, the duty cycle may be determined. The duty cycle may be determined based on a comparison between a value of the max_counter 404 and a value of the on_counter 406. For example, the duty cycle may be a percentage of time the inductor is charging/discharging as measured by the value of the on_counter 406 divided by a total amount of time as measured by the max_counter 404. The duty cycle may be determined in a manner substantially similar to that described above with respect to FIG. 3. The Ipeak circuit may be adjusted based on the determined duty cycle in a manner substantially similar to that described above with respect to FIG. 3.

In some cases, the load of the inductor in burst mode may be inferred (e.g., by the load computation circuit 214 of FIG. 2) based on a number of charge/discharge cycles in a burst cycle. For example, a number of charge/discharge cycles in a single burst cycle, such as burst cycle 414, may be proportional to 1/(load current−Ipeak circuit setting/2). Thus, a higher number of a charge/discharge cycles may indicate a higher load current. In such cases, the Ipeak circuit may be directly adjusted based on the number of charge/discharge cycles in a single burst cycle. For example, a burst cycle having four charge/discharge cycles may have a higher load current than another burst cycle having three charge/discharge cycles and the Ipeak circuit may be adjusted to a higher setting when the burst cycle has four charge/discharge cycles as compared to when the burst cycle has three charge/discharge cycles.

In some cases, the burst mode detector, such as burst mode detector 208 of FIG. 2, may be measure a number of charge/discharge cycles in a burst cycle. For example, as indicated above, the burst mode detector 208 may determine whether the inductor is in burst mode and an end to the burst when a deadtime is reached based on the indication whether the inductor is charging, discharging, or neither. The burst mode detector may also count a number of transitions (e.g., count a number of T_{ON} edges received or T_{ON} edge followed by a T_{OFF} edge) into a recharging cycle (e.g., corresponding to charge/discharge time 410) there are before the deadtime is reached. The number of transitions may indicate the number of charge/discharge cycles. Counting the charge/discharge cycles may end when the deadtime 412 is detected. The number of charge/discharge cycles in the burst cycle 414 (e.g., burst count 230) may be output from the burst mode detector to the Ipeak circuit.

The peak circuit may then be adjusted based on the number of charge/discharge cycles. In some cases, if the number of charge/discharge cycles in the burst cycle is >6, the Ipeak circuit setting may be increased by 1. If the number of charge/discharge cycles in the burst cycle is <3, the Ipeak circuit may be decreased by 1.

In some cases, a load meter may support measuring the load current for an inductor operating in burst mode without supporting measuring the load current for the inductor not operating in burst mode. For example, measuring the load current based on the number of charge/discharge cycles may be implemented using just a burst mode detector, such as burst mode detector 208 of FIG. 2, coupled to an Ipeak circuit.

In some cases, it may also be useful to allow for the Ipeak circuit to be quickly adjusted to account for a voltage undershoot condition. The voltage undershoot condition may occur, for example, when a load current of the inductor rapidly jumps. For example, a load, such as a radio transmitter operating in a low power mode may suddenly exit the low power mode and enter an active mode where a lot more power is used, such as a transmitting mode. This rapid jump in load current may cause the output voltage of the inductor to drop, resulting in the voltage undershoot condition.

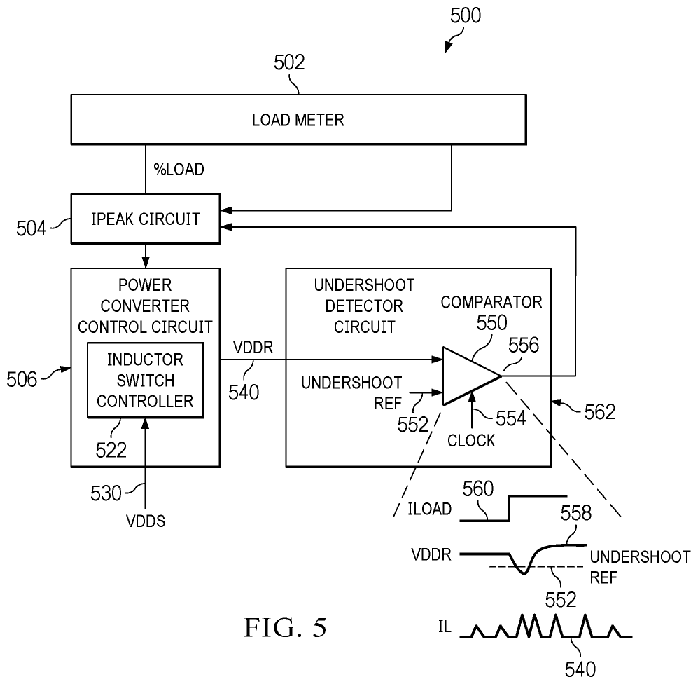

FIG. 5 is a circuit diagram of an adjustable power converter circuit 500 including voltage undershoot detection and mitigation, in accordance with aspects of the present disclosure. FIG. 5 includes a load meter 502 electronically coupled to an Ipeak circuit 504. The Ipeak circuit 504 is electronically coupled to a power converter control circuit 506. In some cases, the load meter 502 may be substantially similar to load meter 202 of FIG. 2. Similarly, Ipeak circuit 504 may be substantially similar to Ipeak circuit 204 of FIG. 2.

The power converter control circuit 506 may include an inductor switch controller 522, and the power converter control circuit 506 may be electronically coupled to a comparator 550 of an undershoot detector circuit 562. The power converter control circuit 506 may include other components as described with respect to power converter control circuit 206 of FIG. 2, which are omitted here for clarity purposes. The inductor switch controller 522 may be substantially similar to inductor switch controller 222. As shown in FIG. 5, the inductor switch controller 222 is coupled to, and receives, a supply voltage 530. As discussed above with respect to FIG. 2, the power converter control circuit 506 may output a regulated voltage 540 and the regulated voltage 540 may be input to the comparator 550. The regulated voltage 540 may be substantially similar to regulated voltage 240 of FIG. 2. The comparator 550 also receives an undershoot reference voltage 552 and a clock signal 554. The comparator 550 is electronically coupled to the Ipeak circuit 504. In some cases, the comparator 550 may compare the regulated voltage 540 to the undershoot reference voltage 552 based on clock cycles of the clock (e.g., clock signal 554). If the regulated voltage 540 drops 558 below the undershoot reference voltage 552 (e.g., due to a load jump 560), the comparator 550 may detect the voltage undershoot condition and output an indication 556 (e.g., the comparator 550 may go high) of the voltage undershoot condition to the Ipeak circuit 504. In some cases, the voltage of the undershoot reference voltage 552 may be set/adjusted, for example, based on a voltage tolerance of the load.

The Ipeak circuit 504 may adjust a setting on the peak circuit 504 to increase the Ipeak value and thereby increase the amount of time the power converter control circuit 506 charges an inductor coupled to the power converter control circuit 506 based on the indication of the voltage undershoot condition. In some cases, the Ipeak circuit 504 may adjust the amount of time the power converter control circuit 506 charges the inductor to a maximum setting based on the indication 556 of the voltage undershoot condition. For example, upon receiving the indication 556 of the voltage undershoot condition, the Ipeak circuit 504 may increase the Ipeak value to a maximum setting. In other cases, the Ipeak circuit 504 setting set based on the indication of the voltage undershoot condition may be configurable, for example, by a memory mapped register. In some cases, the voltage undershoot condition may be detected in one clock cycle (as the comparator 550 may be based on clock cycles of the clock (e.g., clock signal 554)). Thus, adjusting the Ipeak value for voltage undershoot condition can occur rapidly. After the Ipeak circuit 504 and power converter control circuit 506 are adjusted to address the voltage undershoot condition, the Ipeak value may be brought down over time (e.g., when the load is reduced), for example, in a manner similar to that described above with respect to FIG. 3.

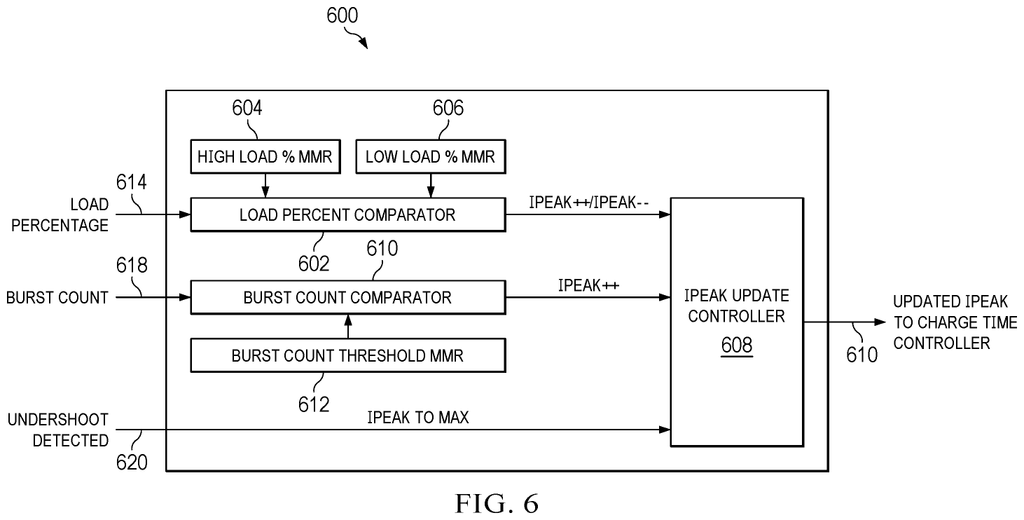

FIG. 6 is a circuit diagram illustrating an Ipeak circuit 600, in accordance with aspects of the present disclosure. In some cases, the Ipeak circuit 600 may correspond to Ipeak circuit 204 of FIG. 2 and Ipeak circuit 504 of FIG. 5. As discussed above, the Ipeak circuit 600 may adjust a peak current that may be driven by an inductor by updating an amount of time a charge time controller may cause the inductor to be charged. The Ipeak circuit 600 shown in FIG. 6 includes a load percent comparator 602 which may be electronically coupled to a high load percentage memory mapped register (MMR) 604 and a low load percentage MMR 606. The load percent comparator 602 may also be electronically coupled to an Ipeak update controller 608. The Ipeak circuit 600 shown in FIG. 6 also includes a burst count comparator 610 electronically coupled to a burst count threshold MMR 612. The burst count comparator 610 is also electronically coupled to the Ipeak update controller 608.

In some cases, such as if the inductor/power converter circuit is operating in a non-burst mode, the load percent comparator 602 may receive an indication of a load percentage 614 of a power converter circuit and coupled inductor, such as the indication of the load percentage output 238 from the load meter 202 of FIG. 2. The load percent comparator 602 may compare the indicated load percentage 614 against a high load percentage value in the high load percentage MMR 604. In some cases, the high load percentage value in the high load percentage MMR 604 and a low load percentage value in the low load percentage MMR 606 may define a range of load percentages (e.g., duty cycles) within which the inductor may operate efficiently. In some cases, the high load percentage value and low load percentage value may be configurable. If the indicated load percentage 614 is greater than the high load percentage value, then the load percent comparator 602 may output an indication to the Ipeak update controller 608 to increase the Ipeak value. The Ipeak update controller 608 may then transmit an updated Ipeak value 616 to increase the amount of time which the inductor is charged, for example, to a charge time controller, such as charge/discharge time calculator 220 of FIG. 2, of a power converter circuit, such as power converter control circuit 206 of FIG. 2.

If the indicated load percentage 614 is less than the high load percentage level, the load percent comparator 602 may compare the indicated load percentage against a low percentage value in the low load percentage MMR 606. If the indicated load percentage 614 is greater than the low percentage value, the load percent comparator 602 may not send an indication to change the Ipeak value. If the indicated load percentage 614 is less than the low percentage value, the load percent comparator 602 may send an indication to the Ipeak update controller 608 to decrease the Ipeak value. The Ipeak update controller 608 may then transmit an updated Ipeak value 616 to decrease the amount of time which the inductor is charged, for example, to the charge time controller, such as charge/discharge time calculator 220 of FIG. 2, of a power converter circuit, such as power converter control circuit 206 of FIG. 2.

In some cases, such as if the inductor/power converter circuit is operating in a burst mode, the burst count comparator 610, may receive a burst count value 618, for example, from a burst mode detector, such as burst mode detector 208 of FIG. 2. The burst count comparator 610 may compare the burst count value 618 to a burst count threshold value from the burst count threshold MMR 612. In some cases, the burst count threshold value may be configurable. If the burst count value 618 does not exceed the burst count threshold, the burst count comparator 610 may not indicate a change in the Ipeak value to the Ipeak update controller 608. If the burst count value 618 exceeds the burst count threshold, the burst count comparator 610 may output an indication to the Ipeak update controller 608 to increase the Ipeak value. The Ipeak update controller 608 may then transmit an updated Ipeak value 616 to increase the amount of time which the inductor is charged, for example, to a charge time controller, such as charge/discharge time calculator 220 of FIG. 2, of a power converter circuit, such as power converter control circuit 206 of FIG. 2.

In some cases, such as if a regulated voltage drops below a reference voltage, the Ipeak update controller 608 may receive an indication that a voltage undershoot has been detected 620. If the Ipeak update controller 608 receives the indication that the voltage undershoot has been detected 620, the Ipeak update controller may then transmit an updated Ipeak value 616 adjusting the Ipeak value 616 to a maximum value.

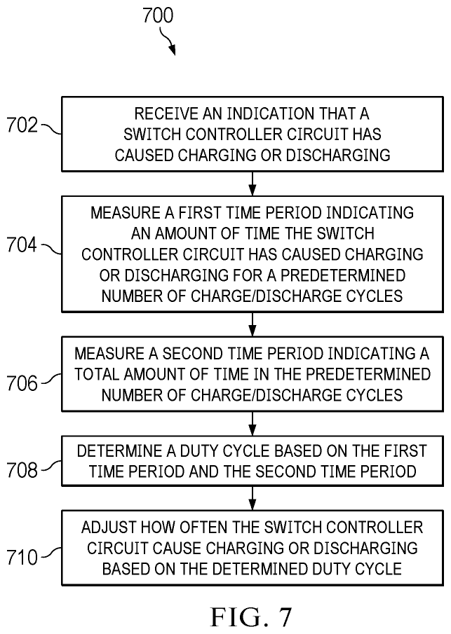

FIG. 7 is a flow diagram 700 illustrating an overview of a technique for controlling a power converter, in accordance with aspects of the present disclosure. At block 702, an indication that a switch controller circuit has caused charging or discharging of an energy storage device is received. As an example, a charge/discharge time counter circuit may receive an indication of a T_{ON} state indicating that an energy storage device of a charging circuit, such as an inductor, is being charged. The charge/discharge time counter circuit may also receive an indication of a T_{OFF} state indicating that the energy storage device is being discharged.

At block 704, a first time period indicating an amount of time the switch controller circuit has caused charging or discharging is measured for a predetermined number of charge/discharge cycles. As an example, a charge/discharge time counter circuit may measure an amount of time spent charging and discharging an energy storage device of a charging circuit over a predetermined number of charge/discharge cycles. In some cases, the predetermined number of charge/discharge cycles is configurable. In some examples, the amount of time may be measured based on clock cycles (e.g., clock ticks). In some cases, the energy storage device may be an inductor and/or capacitor.

At block 706, a second time period indicating a total amount of time in the predetermined number of charge/discharge cycles is measured. In some cases, in non-burst operation (e.g., DCM) a charge/discharge cycle may be followed by a deadtime. In some cases, a deadtime may be where the energy storage device is neither charging, nor discharging. The total amount of time may include the time spent charging and discharging, along with the deadtimes associated with the predetermined number of charge/discharge cycles. In some cases, a deadtime may be detected and a number of detected deadtimes may be compared to the predetermined number of charge/discharge cycles to determine whether to determine a duty cycle. In some examples, a charge/discharge cycle comprises at least one charge cycle for charging the energy storage device, one discharge cycle for discharging the energy storage device, and a deadtime where the energy storage device is neither charged nor discharged. In some cases, the deadtime may occur when the energy storage device is neither charged nor discharged for more than a predetermined amount of time. In some cases, the predetermined number of charge/discharge cycles is configurable.

At block 708, a duty cycle may be determined based on the first time period and the second time period. In some cases, the duty cycle may be determined by dividing the second time period by the first time period. In some examples, the duty cycle is determined based on bit shifting.

At block 710, how often charging or discharging is caused (e.g., of an inductor) by the switch controller circuit (e.g., inductor switch controller 222 of FIG. 2) may be adjusted based on the determined duty cycle.

In some cases, a burst mode may be detected based on a number of charge and discharge cycles in a burst cycle. In some examples, the inductor peak current circuit may be adjusted based on the number of charge and discharge cycles in the burst cycle. In some cases, how often the inductor switch controller circuit cause charging or discharging may be adjusted based on the number of charge/discharge cycles in the burst cycle.

In some examples, a comparator may compare a voltage of the output of the power converter circuit and a reference voltage to determine that the output voltage has dropped below the reference voltage and adjust the inductor peak current circuit based on the determination that the output voltage has dropped below the reference voltage. In some cases, the inductor peak current may be adjusted to a maximum setting.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

A device that is “configured to” perform a task or function may be configured (e.g., programmed and/or hardwired) at a time of manufacturing by a manufacturer to perform the function and/or may be configurable (or re-configurable) by a user after manufacturing to perform the function and/or other additional or alternative functions. The configuring may be through firmware and/or software programming of the device, through a construction and/or layout of hardware components and interconnections of the device, or a combination thereof.

A circuit or device that is described herein as including certain components may instead be adapted to be coupled to those components to form the described circuitry or device. Circuits described herein are reconfigurable to include additional or different components to provide functionality at least partially similar to functionality available prior to the component replacement. Modifications are possible in the described examples, and other examples are possible within the scope of the claims.

Illustrative aspects of the disclosure include:

Aspect 1. An apparatus comprising: a switch controller couplable to a power converter circuit, wherein the switch controller is configured to cause charging or discharging of the power converter circuit; a first counter circuit configured to receive an indication that the switch controller circuit has caused charging or discharging, wherein the first counter circuit is configured to measure a first time period indicating an amount of time the switch controller circuit has caused charging or discharging for a predetermined number of charge/discharge cycles; a second counter circuit configured to receive an indication that the switch controller circuit has caused charging or discharging, wherein the second counter circuit is configured to measure a second time period indicating a total amount of time in the predetermined number of charge/discharge cycles; and a load computation circuit coupled to the first counter circuit and the second counter circuit, wherein the load computation circuit is configured to: determine a duty cycle based on the first time period and the second time period; and adjust how often the switch controller circuit causes charging or discharging based on the determined duty cycle.

Aspect 2. The apparatus of Aspect 1, wherein the first time period and the second time period are measured based on a number of clock cycles.

Aspect 3. The apparatus of any of Aspects 1-2, wherein the predetermined number of charge/discharge cycles is configurable.

Aspect 4. The apparatus of any of Aspects 1-3, wherein the duty cycle is determined by dividing the first time period by the second time period.

Aspect 5. The apparatus of any of Aspects 1-4, wherein the duty cycle is determined based on bit shifting.

Aspect 6. The apparatus of any of Aspects 1-5, further comprising a burst mode detection circuit configured to receive an indication that the switch controller circuit has caused charging or discharging, wherein the burst mode detection circuit is configured to detect a burst mode based on a number of charge cycles and discharge cycles in a burst cycle.

Aspect 7. The apparatus of Aspect 6, wherein the burst mode detection circuit is further configured to adjust how often the switch controller circuit causes charging or discharging based on the number of charge/discharge cycles in the burst cycle.

Aspect 8. The apparatus of any of Aspects 6-7, wherein the burst mode detection circuit is further configured to: detect a deadtime; and compare a number of detected deadtimes to the predetermined number of charge/discharge cycles to determine whether to determine the duty cycle.

Aspect 9. The apparatus of any of Aspects 1-8, wherein the switch controller is coupled to one or more drivers configured to couple a power source and an energy storage device.

Aspect 10. The apparatus of Aspect 9, wherein the charge/discharge cycle comprises at least one charge cycle for charging the energy storage device, one discharge cycle for discharging the energy storage device, and a deadtime where the energy storage device is neither charged nor discharged.

Aspect 11. The apparatus of Aspect 10, wherein the deadtime comprises neither charging nor discharging the energy storage device for more than a predetermined amount of time.

Aspect 12. The apparatus of any of Aspects 1-11, further comprising a comparator coupled to an output of the power converter circuit, wherein the comparator is configured to: compare an output voltage of the power converter circuit and a reference voltage to determine that the output voltage has dropped below the reference voltage; and adjust how often the switch controller circuit causes charging or discharging based on the determination that the output voltage has dropped below the reference voltage.

Aspect 13. The apparatus of Aspect 12, wherein, to adjust how often the switch controller circuit causes charging or discharging based on the determination that the output voltage has dropped below the reference voltage, the comparator is configured to adjust how often the switch controller circuit causes charging or discharging to a maximum setting.

Aspect 14. A system for power conversion, comprising: a power converter circuit including one or more drivers configured to couple a power source to an energy storage device that is coupled to a load; a first counter circuit coupled to the power converter circuit, wherein the first counter circuit is configured to measure a first time period indicating an amount of time for recharging and discharging the power converter circuit for a predetermined number of charge/discharge cycles; a second counter circuit coupled to the power converter circuit, wherein the second counter circuit is configured to measure a second time period indicating a total amount of time in the predetermined number of charge/discharge cycles; and a duty cycle circuit coupled to the first counter circuit and the second counter circuit, wherein the duty cycle circuit is configured to: determine a duty cycle of the power converter circuit based on the first time period and the second time period; and adjust an amount of time the power converter circuit is charged or discharged based on the determined duty cycle.

Aspect 15. The system of Aspect 14, wherein the first time period and the second time period are measured based on a number of clock cycles.

Aspect 16. The system of any of Aspects 14-15, wherein the predetermined number of charge/discharge cycles is configurable.

Aspect 17. The system of any of Aspects 14-16, wherein the duty cycle is determined by dividing the first time period by the second time period.

Aspect 18. The system of any of Aspects 14-17, wherein the duty cycle is determined based on bit shifting.

Aspect 19. The system of any of Aspects 14-18, further comprising a burst mode detection circuit configured to receive an indication that the power converter circuit is charging or discharging, wherein the burst mode detection circuit is configured to detect a burst mode based on a number of charge cycles and discharge cycles in a burst cycle.

Aspect 20. The system of any of Aspects 14-19, further comprising a comparator coupled to an output of the power converter circuit, wherein the comparator is configured to: compare an output voltage of the power converter circuit and a reference voltage to determine that the output voltage has dropped below the reference voltage; and adjust the amount of time the power converter circuit is charged or discharged based on the determination that the output voltage has dropped below the reference voltage.

What is claimed is:

1. An apparatus comprising:
a switch controller couplable to a power converter circuit, wherein the switch controller is configured to cause charging or discharging of the power converter circuit;
a first counter circuit configured to receive an indication that the switch controller circuit has caused charging or discharging, wherein the first counter circuit is configured to measure a first time period indicating an amount of time the switch controller circuit has caused charging or discharging for a predetermined number of charge/discharge cycles;
a second counter circuit configured to receive an indication that the switch controller circuit has caused charging or discharging, wherein the second counter circuit is configured to measure a second time period indicating a total amount of time in the predetermined number of charge/discharge cycles; and
a load computation circuit coupled to the first counter circuit and the second counter circuit, wherein the load computation circuit is configured to:
determine a duty cycle based on the first time period and the second time period; and
adjust how often the switch controller circuit causes charging or discharging based on the determined duty cycle.

2. The apparatus of claim 1, wherein the first time period and the second time period are measured based on a number of clock cycles.

3. The apparatus of claim 1, wherein the predetermined number of charge/discharge cycles is configurable.

4. The apparatus of claim 1, wherein the duty cycle is determined by dividing the first time period by the second time period.

5. The apparatus of claim 1, wherein the duty cycle is determined based on bit shifting.

6. The apparatus of claim 1, further comprising a burst mode detection circuit configured to receive an indication that the switch controller circuit has caused charging or discharging, wherein the burst mode detection circuit is configured to detect a burst mode based on a number of charge cycles and discharge cycles in a burst cycle.

7. The apparatus of claim 6, wherein the burst mode detection circuit is further configured to adjust how often the switch controller circuit causes charging or discharging based on the number of charge/discharge cycles in the burst cycle.

8. The apparatus of claim 6, wherein the burst mode detection circuit is further configured to: detect a deadtime; and
compare a number of detected deadtimes to the predetermined number of charge/discharge cycles to determine whether to determine the duty cycle.

9. The apparatus of claim 1, wherein the switch controller is coupled to one or more drivers configured to couple a power source and an energy storage device.

10. The apparatus of claim 9, wherein the charge/discharge cycle comprises at least one charge cycle for charging the energy storage device, one discharge cycle for discharging the energy storage device, and a deadtime where the energy storage device is neither charged nor discharged.

11. The apparatus of claim 10, wherein the deadtime comprises neither charging nor discharging the energy storage device for more than a predetermined amount of time.

12. The apparatus of claim 1, further comprising a comparator coupled to an output of the power converter circuit, wherein the comparator is configured to:
compare an output voltage of the power converter circuit and a reference voltage to determine that the output voltage has dropped below the reference voltage; and
adjust how often the switch controller circuit causes charging or discharging based on the determination that the output voltage has dropped below the reference voltage.

13. The apparatus of claim 12, wherein, to adjust how often the switch controller circuit causes charging or discharging based on the determination that the output voltage has dropped below the reference voltage, the comparator is configured to adjust how often the switch controller circuit causes charging or discharging to a maximum setting.

14. A system for power conversion, comprising:
a power converter circuit including one or more drivers configured to couple a power source to an energy storage device that is coupled to a load;
a first counter circuit coupled to the power converter circuit, wherein the first counter circuit is configured to measure a first time period indicating an amount of time for recharging and discharging the power converter circuit for a predetermined number of charge/discharge cycles;
a second counter circuit coupled to the power converter circuit, wherein the second counter circuit is configured to measure a second time period indicating a total amount of time in the predetermined number of charge/discharge cycles; and
a duty cycle circuit coupled to the first counter circuit and the second counter circuit, wherein the duty cycle circuit is configured to:
determine a duty cycle of the power converter circuit based on the first time period and the second time period; and
adjust an amount of time the power converter circuit is charged or discharged based on the determined duty cycle.

15. The system of claim 14, wherein the first time period and the second time period are measured based on a number of clock cycles.

16. The system of claim 14, wherein the predetermined number of charge/discharge cycles is configurable.

17. The system of claim 14, wherein the duty cycle is determined by dividing the first time period by the second time period.

18. The system of claim 14, wherein the duty cycle is determined based on bit shifting.

19. The system of claim 14, further comprising a burst mode detection circuit configured to receive an indication that the power converter circuit is charging or discharging, wherein the burst mode detection circuit is configured to detect a burst mode based on a number of charge cycles and discharge cycles in a burst cycle.

20. The system of claim 14, further comprising a comparator coupled to an output of the power converter circuit, wherein the comparator is configured to:
compare an output voltage of the power converter circuit and a reference voltage to determine that the output voltage has dropped below the reference voltage; and
adjust the amount of time the power converter circuit is charged or discharged based on the determination that the output voltage has dropped below the reference voltage.
